(19) United States
(12) Patent Application Publication
(10) Pub. No.: US 2015/0012760 A1
(43) Pub. Date: Jan. 8, 2015

(54) INFORMATION PROCESSING APPARATUS AND POWER SUPPLY CONTROL METHOD

(71) Applicant: FUJITSU LIMITED, Kawasaki-shi (JP)

(72) Inventor: MASAO SHICHI, Kawasaki (JP)

(21) Appl. No.: 14/492,885

(22) Filed: Sep. 22, 2014

Related U.S. Application Data
(63) Continuation-in-part of application No. PCT/JP2012/058708, filed on Mar. 30, 2012.

(51) Int. Cl. H05K 7/14; G06F 1/26

(52) U.S. Cl. CPC H05K 7/1492; G06F 1/26; H05K 7/1414
USPC 713/300

(57) ABSTRACT

An information processing apparatus including a removable board, the board including a first control circuit which controls the board, a second control circuit which controls a power supply of the first control circuit, a first locking unit which is capable of locking the board and releasing a locking of the board, a second locking unit which locks the first locking unit, and a lock switch which turns on when the first locking unit is locked by the second locking unit; and the second control circuit turns on the power supply of the first control circuit when the lock switch is on.

### CROSS-REFERENCE TO RELATED APPLICATION

This application is a continuation application of International Application PCT/JP2012/058708 filed on Mar. 30, 2012 and designated the U.S., the entire contents of which are incorporated herein by reference.

### FIELD

The embodiments discussed herein are related to an information processing apparatus and a power supply control method.

### BACKGROUND

The Advanced Telecom Computing Architecture (ATCA) is an international standard established by the PCI Industrial Computer Manufacturers Group (PICMG) for telecommunications carriers.

The ATCA defines hardware specifications for the chassis and the board (blade) inserted into the chassis. According to the ATCA, the standard interface IPMI (Intelligent Platform Management Interface) is used for monitoring the hardware, and the temperature, the voltage, the power supply and the like on the board are monitored by implementing the IPMC (Intelligent Platform Management Controller) on the control circuit on the board.

In addition, a (hotswap) function with which the board may be inserted and removed while the chassis power is on is provided, and it is defined that the turning on and off of the power supply of a board in accordance with the ATCA standard is controlled by an ejector used at the time of the insertion and removal.

When the board is inserted into the chassis, power is supplied from the chassis to the board to make the control circuit on the board operate, and the board power supply is turned on by further controlling the ejector, to make the main circuit on the board operate.

FIG. 1 is a configuration diagram of a conventional server.

A server 1101 is equipped with a chassis 1201 and a board 1301.

The chassis 1201 is a casing that stores the board 1301.

The chassis 1201 is equipped with a chassis control module 1202, a power supply module 1204, and a backplane 1205.

The chassis control module 1202 is a board on which a circuit that performs processes such as a process to monitor the chassis 1201 and a process to receive reports from the board 1301 is mounted.

The power supply module 1204 is a power supply apparatus that supplies power to the chassis control module 1202 and to the board 1301.

The backplane 1205 is a circuit board provided with a connector 1206 that connects to the board 1301, a bus that performs communication between the boards 1301 and with the chassis control module 1202, and the like. The backplane 1205 connects to the power supply module 1204, and power to the board 1301 is supplied through the connector 1206.

The board 1301 is equipped with a control circuit 1311, a main circuit 1321, a voltage and temperature sensor 1331, a connector 1341, ejectors 1361-1 and 1361-2, and a power supply switch 1371.

The control circuit 1311 is equipped with a primary power supply 1312, a board monitoring circuit 1313, a power supply control circuit 1314, and a power supply switch (SW) monitoring circuit 1315.

The primary power supply 1312 receives power supply from the power supply module 1204 while the connector 1341 is connected to the connector 1206, and the primary power supply 1312 supplies power to the control circuit 1311.

The board monitoring circuit 1313 reports the state of the board 1301 to the chassis control module 1202.

The power supply control circuit 1314 controls a turning on and off of the board power supply 1328. Specifically, the power supply control circuit 1314 turns on the board power supply 1328 when the power supply switch 1371 turns on, and the power supply control circuit 1314 turns off the board power supply 1328 when the power supply switch 1371 turns off.

The power supply switch monitoring circuit 1315 monitors the power supply switch 1371, and the power supply switch monitoring circuit 1315 reports the state (on or off) of power supply switch 1371 to the power supply control circuit 1314.

The main circuit 1321 is equipped with a circuit (not illustrated in the drawing) that executes various processes, and a board power supply 1328.

The board power supply 1328 supplies power to the main circuit 1321.

The voltage and temperature sensor 1331 measures the voltage supplied to the board 1301 and the temperature of the board, and the voltage and temperature sensor 1331 reports them to the board monitoring circuit 1313.

The connector 1341 is a connector that connects to the connector 1206 of the backplane 1205 and that performs power supply from the power supply module 1204 and performs input and output of signals with a chassis control module 1202.

FIG. 2A is a diagram of an ejector during the insertion of a conventional board.

FIG. 2B is a diagram of an ejector after the insertion of a conventional board.

FIG. 2C is a diagram of an ejector while the conventional ejector is locked.

Meanwhile, FIG. 2A through 2C are an enlarged view of the ejector 1361-1.

The ejector 1361-1 is equipped with a lock unit 1362-1 that fixes the ejector 1361-1 and restrains the movement of the ejector 1361-1.

When the board 1301 is inserted into the chassis 1201, the power supply switch 1371 is not pressed down and it is in the off state (FIG. 2A). When the insertion of the board 1301 into the chassis 1201 is completed, the power supply switch 1371 is pressed by the lock unit 1362-1 attached to the ejector 1361-1, and the power supply switch 1371 is put into the on state (FIG. 2B).

When there is contact with the ejector 1361-1, this makes the ejector 1361-1 move, causing a malfunction in which the power supply switch 1371 turns off and the board power supply turns off. In order to prevent such a situation from emerging, the user makes the lock unit 1362-1 slide so as to lock the ejector 1361-1 so that the ejector 1361-1 does not move (FIG. 2C). Accordingly, a malfunction of the board power supply is prevented.

Conventional servers are not equipped with any means for detecting the unlocked state of the ejector. Therefore, cases exist in which the operator forgets to lock the ejector when inserting the board, or in which a cable and the like touches the lock unit in a maintenance task performed during the operation of the board, putting the ejector into the unlocked state.

When the ejector is in the unlocked state, there is a problem wherein an accident may occur such as contact with the ejector causing a malfunction such as the turning off of the power supply switch, and the like.

Furthermore, documents such as Japanese Laid-open Utility Model Publication No. 5-87992, Japanese Laid-open Patent Publication No. 5-204506, Japanese Laid-open Patent Publication No. 2007-317953, Japanese Laid-open Patent Publication No. 2008-218835, etc. are well known.

### SUMMARY

According to an aspect of the invention, an information processing apparatus includes a removable board.

The board includes a first control circuit, a second control circuit, a first locking unit, a second locking unit, and a lock switch.

The first control circuit controls the board.

The second control unit controls the power supply of the first control circuit.

The first locking unit makes it possible to lock the board and to release the locking of the board.

The second locking unit locks the first locking unit.

The lock switch turns on when the first locking unit is locked by the second locking unit.

The second control circuit turns on the power supply of the first control circuit when the lock switch is on.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a configuration diagram of a conventional server;

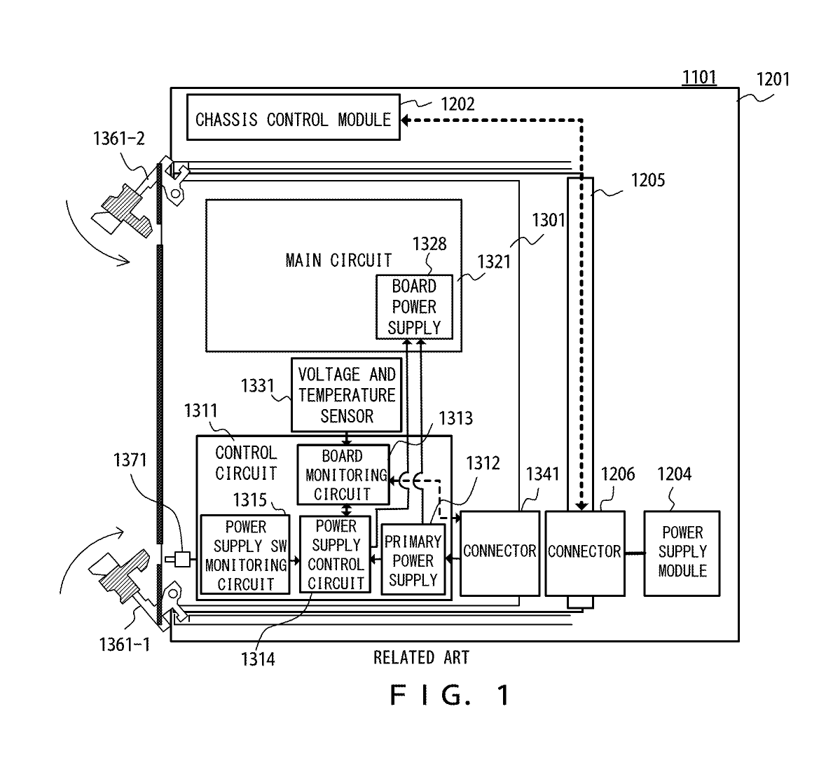

FIG. 2A is a diagram of an ejector during the insertion of a conventional board;

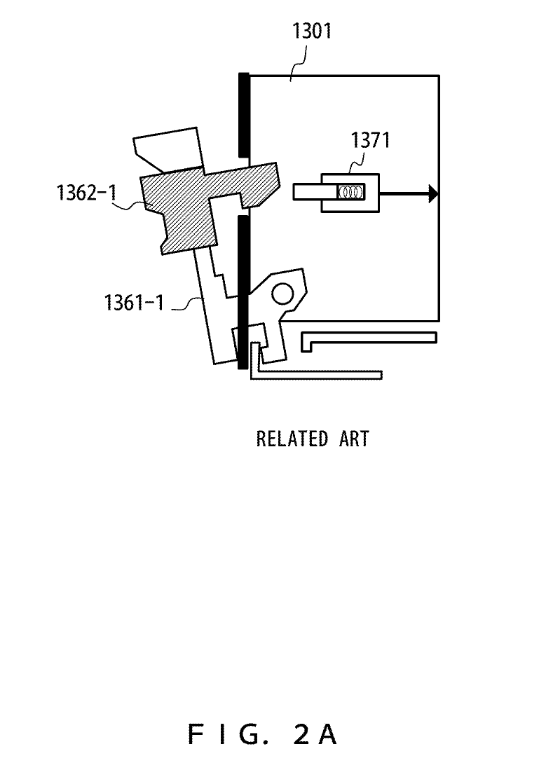

FIG. 2B is a diagram of an ejector after the insertion of a conventional board;

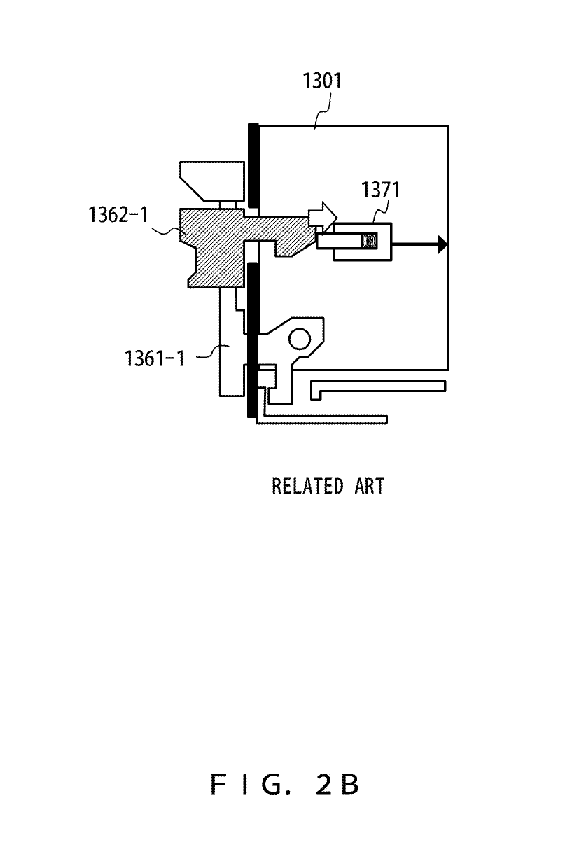

FIG. 2C is a diagram of an ejector while the conventional ejector is locked;

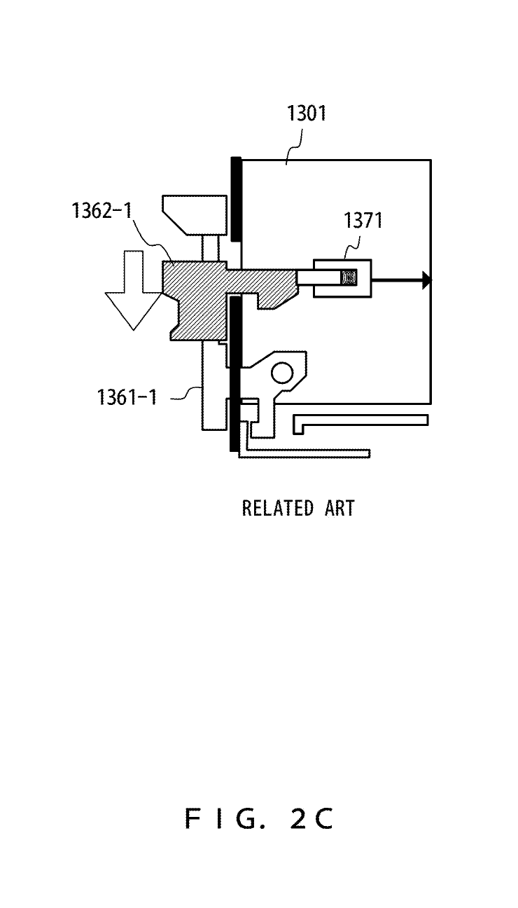

FIG. 3 is a perspective view of a server according to an embodiment;

FIG. 4 is a functional block diagram of a server according to an embodiment;

FIG. 5 is a detailed configuration diagram of a chassis and a board according to an embodiment;

FIG. 6A is a diagram of an ejector according to an embodiment in the unlocked state;

FIG. 6B is a diagram illustrating the movement of an ejector according to an embodiment;

FIG. 6C is a diagram of an ejector according to an embodiment in the locked state;

FIG. 7A is a diagram of an ejector during the insertion of a board according to an embodiment;

FIG. 7B is a diagram of an ejector after the insertion of a board according to an embodiment;

FIG. 7C is a configuration diagram of an ejector while the ejector is locked according to an embodiment;

FIG. 8 is a diagram illustrating the configuration and operations of an ejector according to an embodiment;

FIG. 9 is a sequence diagram of a power supply control process according to an embodiment;

FIG. 10 is a timing chart illustrating the state of a board according to an embodiment;

FIG. 11 is a diagram illustrating the state of a board before the insertion of the board;

FIG. 12 is a diagram illustrating the state of a board at the time of the completion of the insertion of the board;

FIG. 13 is a diagram illustrating the state of a board while an ejector is in the locked state;

FIG. 14 is a diagram illustrating the state of a board while the board power supply is on;

FIG. 15 is a diagram illustrating the state of a board while an ejector is in the unlocked state;

FIG. 16 is a diagram illustrating the state of a board after a prescribed period of time since an ejector was put into the unlocked state;

FIG. 17 is a diagram illustrating the state of a board while the ejector is open; and

FIG. 18 is a diagram illustrating the state of a board while the board power supply is off.

### DESCRIPTION OF EMBODIMENTS

Hereinafter, an embodiment is explained with reference to the drawings.

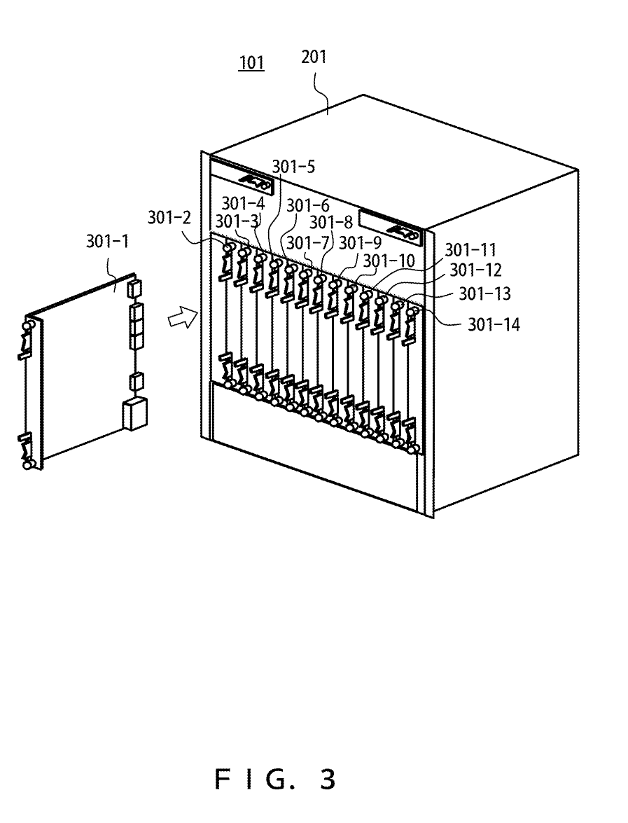

FIG. 3 is a perspective view of a server according to the embodiment.

The server 101 is an example of an information processing apparatus (a computer), and it is, for example, a telecommunication server.

The server 101 is equipped with a chassis 201 and boards 301-i (i=1 through 14).

The chassis 201 is a casing that stores the boards 301. The chassis 201 is equipped with a control module that monitors the chassis 201, a backplane that connects the chassis 201 and the boards 301, a power supply module that supplies power to the boards 301, and the like.

A slot for storing the board 301 is provided in the chassis 201, and a rail for guiding the board 301 to the backplane is provided in the slot. The board 301 is inserted into the chassis 201 along the rail, and the board 301 connects to the backplane in the chassis 201.

The board 301 is a circuit board on which various circuits are mounted. The board 301 is, for example, a server blade, a switch blade, or the like. The board 301 is, for example, an ATCA-compliant board (ATCA board).

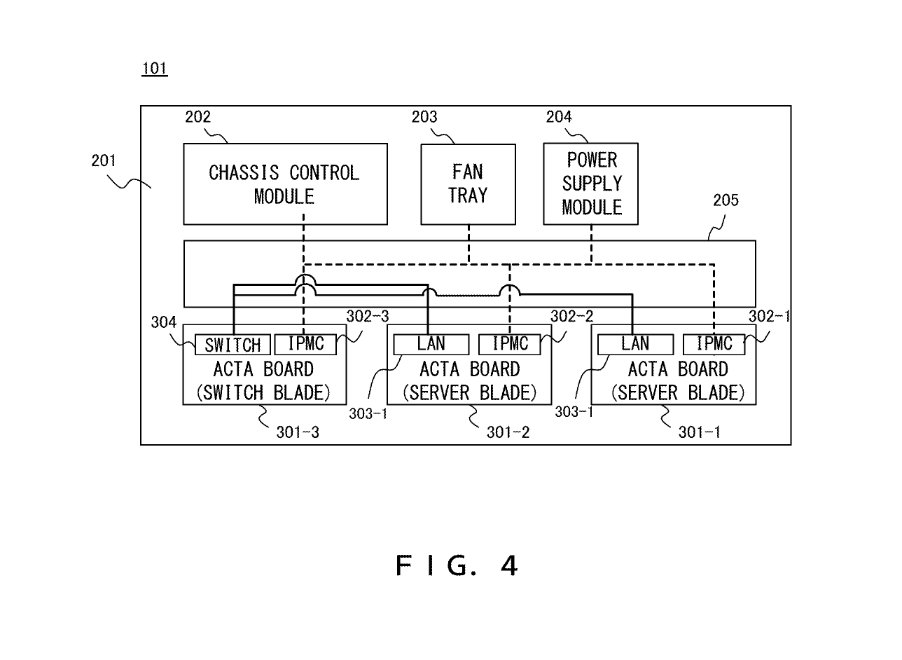

FIG. 4 is a functional block diagram of the server according to the embodiment.

The server 101 is equipped with the chassis 201 and the boards 301-i.

The boards 301-i are stored within the chassis 201.

Meanwhile, in FIG. 4, only the boards 301-1 through 303-3 are illustrated, and the other boards are omitted.

The chassis 201 is equipped with a chassis control module 202, a fan tray 203, a power supply module 204, and a backplane 205.

The chassis control module 202 is a board on which a circuit that executes processes such as a process to monitor the chassis 201 and a process to receive reports from the board 301 is mounted.

The fan tray 203 is a tray on which a fan that draws the air into the chassis 201 or discharges the air out of the chassis 201 is mounted.

The power supply module 204 is a power supply apparatus that supplies power to the chassis control module 202 and to the board 301.

The backplane 205 is a circuit board provided with a connector to connect with the board 301, a bus that performs communication between boards 301 and between boards 301 and the chassis control module 202, and the like. For example, the Intelligent Platform Management Bus (IPMB) may be used as the bus.

The board 301 is a circuit board on which various circuits are mounted, and it is an ATCA-compliant board (ATCA board). The board 301 is connected to a backplane 205.

The Intelligent Platform Management Interface (IPMI) that is a standard interface for monitoring hardware is used for the board 301.

The boards 301-1 and 301-2 are a server blade on which a circuit that has the function of a server is mounted.

The board 301-3 is a switchblade that has a network switch function.

The boards 301-1 through 301-3 are equipped with control circuit 302-1 through 302-3, respectively, and the Intelligent Platform Management Controller (IPMC) is implemented on each of the control circuit 302-1 through 302-3.

The boards 301-1 and 301-2 are equipped with LAN chips 303-1 and 303-2 that perform communication, respectively, the board 301-3 is equipped with a network switch 304 that performs relaying of data and the like, and the boards 301 are connected by an Ethernet.

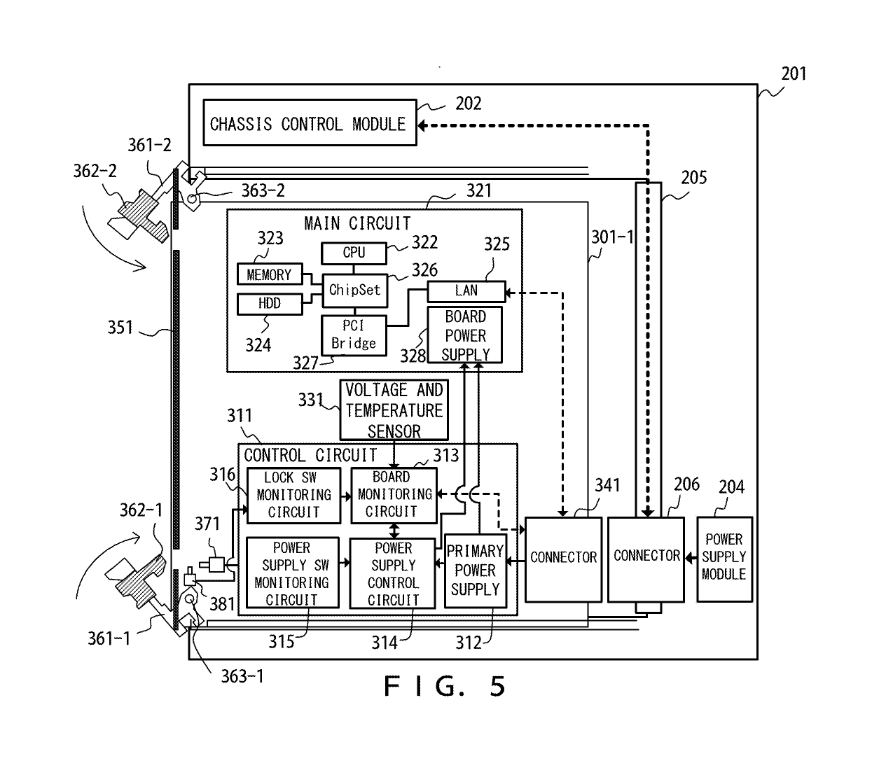

FIG. 5 is a detailed configuration diagram of the chassis and the board according to the embodiment.

Meanwhile, in FIG. 5, only the board 301-1 is illustrated, and the other boards are omitted.

The chassis 201 is equipped with the chassis control module 202, the power supply module 204, and the backplane 205.

The chassis control module 202 is a board on which a circuit that executes processes such as a process to monitor the chassis 201 and a process to receive reports from the board 301 is mounted.

The power supply module 204 is a power supply apparatus that supplies power to the chassis control module 202 and to the board 301.

The backplane 205 is a circuit board provided with connectors 206 that connect to the boards 301, a bus that performs communication between the boards 301 and between the boards 301 and the chassis control module 202, and the like. The backplane 205 connects to the power supply module 204, and the power to the board 301 is supplied through the connector 206.

The board 301-1 is equipped with a control circuit 311, a main circuit 321, a voltage and temperature sensor 331, a connector 341, a front plate 351, ejectors 361-1 and 361-2, a power supply switch 371, and a lock switch 381.

The control circuit 311 is equipped with a primary power supply 312, a board monitoring circuit 313, a power supply control circuit 314, a power supply switch (SW) monitoring circuit 315, and a lock switch monitoring circuit 316.

The primary power supply 312 receives power from the power supply module 204 while the connector 341 is connected to the connector 206, and the primary power supply 312 supplies power to the control circuit 311.

The board monitoring circuit 313 reports the state of the board 301-1 to the chassis control module 202.

The power supply control circuit 314 controls the turning on and off of a board power supply 328.

The power supply switch monitoring circuit 315 monitors the power supply switch 371, and the power supply switch monitoring circuit 315 reports the state (on or off) of the power supply switch 371 to the power supply control circuit 314.

The lock switch monitoring circuit 316 monitors the lock switch 381, and the lock switch monitoring circuit 316 reports the state (on or off) of the lock switch 381 to the power supply control circuit 314.

The main circuit 321 is equipped with a Central Processing Unit (CPU) 322, a memory 323, a hard disk drive (HDD) 324, a LAN chip 325, a chip set 326, a PCI Bridge 327, and the board power supply 328.

The main circuit 321 controls the board 301-1.

The CPU 322 is a processor that executes various processes.

The memory 323 is a storage apparatus that temporarily stores data. The memory 323 is, for example, a Random Access Memory (RAM).

The HDD 324 is a storage apparatus that stores data. The HDD 324 is, for example, a magnetic disk apparatus. In addition, a semiconductor storage apparatus such as a Solid State Drive (SSD) may also be used as the HDD 324.

The LAN chip 325 is a circuit that performs transmission and reception of data.

The chip set 326 is a circuit that performs control of the data delivery between the CPU 322 and memory 323, and the like.

The PCI Bridge 327 is a circuit that controls the PCI bus.

The board power supply 328 is a power supply that supplies power to the main circuit 321.

The voltage and temperature sensor 331 monitors the voltage supplied to the board 301-1 and the temperature of the board, and the voltage and temperature sensor 331 reports them to the board monitoring circuit 313.

The connector 341 is a connector that connects to the connector 206 of the backplane 205 and that performs power supply from the power supply module 204 and performs input and output of signals with a chassis control module 202.

The front plate 351 is a plate provided at an end of the board on which the control circuit 311 and the main circuit 321 are mounted, at a right angle to the board.

The ejectors 361-1 and 361-2 are a lever-like member that is used for the insertion and removal of the board. The ejectors 361-1 and 361-2 are an example of a first locking unit.

The ejectors 361-1 and 361-2 are rotatable around fulcrums 363-1 and 363-2, respectively, and the ejectors 361-1 and 361-2 are respectively attached to a corner portion of the board 301-1.

When the board 301-1 is inserted into the chassis 201 and the ejectors 361-1 and 361-2 are rotated in the direction in which the tip of the ejector 361-1 and 362-2 approaches the front plate 351, the board 301-1 is locked on the chassis 201.

When the ejectors 361-1 and 361-2 are rotated in a direction in which the tip of the ejectors 361-1 and 361-2 moves away from the front plate 351 by an angle that is equal to or greater than a prescribed angle, the board 301-1 is pushed out of the chassis 201 (locking release), and it becomes possible to remove the board 301-1.

The ejectors 361-1 and 361-2 are equipped with lock units 362-1 and 362-2 that lock the ejector 361-1 and 361-2, respectively. The lock units 362-1 and 362-2 are knobs that lock the ejector 361-1 and 361-2 by sliding in a prescribed direction. The lock units 362-1 and 362-2 are an example of a second locking unit.

The lock unit 362-1 attached to the ejector 361-1 presses the power supply switch 371 and the lock switch 381 down according to the position of the lock unit 362-1.

The power supply switch 371 is a push switch that is pressed down by the lock unit 362-1 when the board 301-1 is inserted into the chassis 201 and locked on the chassis 201.

The lock switch 381 is a push switch that is pressed down by the lock unit 362-1 when the lock unit 362-1 slides and the ejector 361-1 is locked.

The power supply switch 371 and the lock switch 381 are an automatic-recovery type switch (a momentary switch) which has a spring inside and which turns on only while it is being pressed down.

Next, the locking of the ejector is explained.

Meanwhile, the structure of the ejector 361-1 and the structure of the ejector 361-2 are the same, and therefore explanation is given here only for the ejector 361-1.

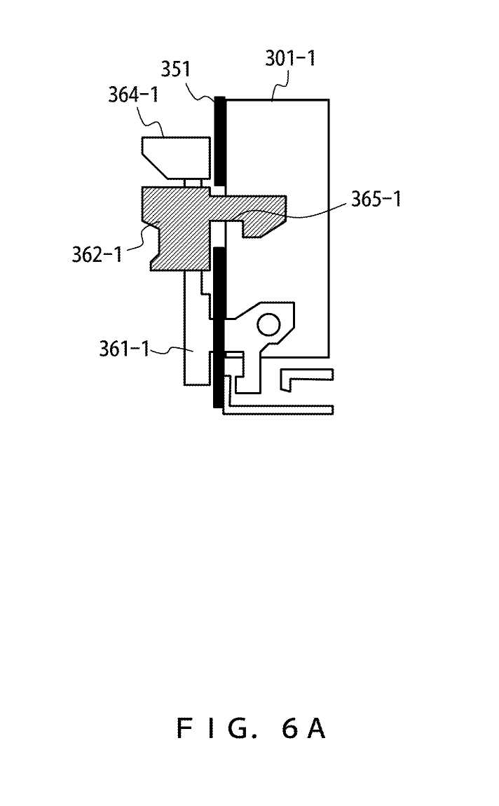

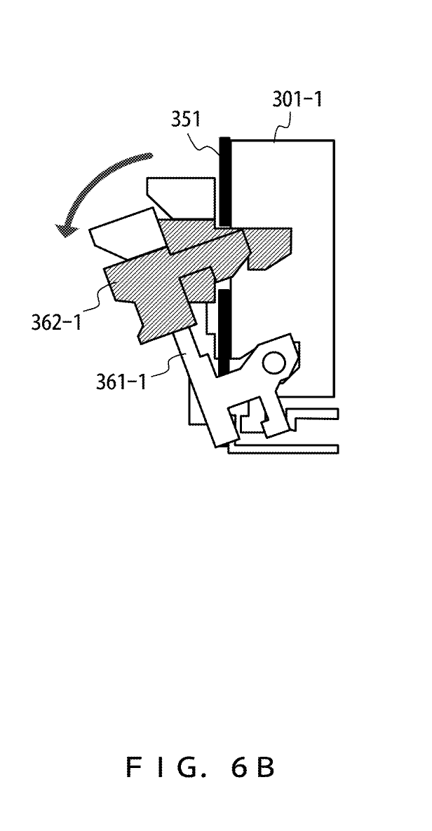

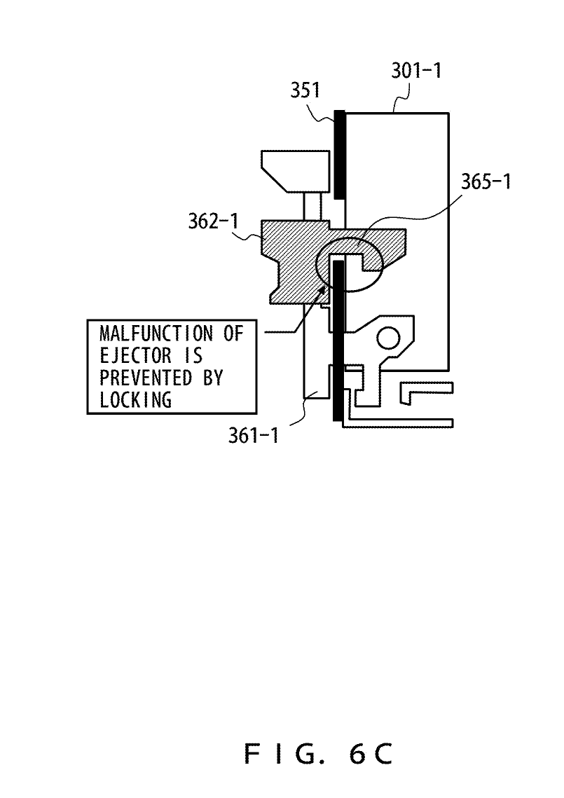

FIG. 6A is a diagram of the ejector according to the embodiment in the unlocked state.

FIG. 6B is a diagram illustrating the movement of the ejector according to the embodiment.

FIG. 6C is a diagram of the ejector according to the embodiment in the locked state.

After the insertion of the board 301-1, when the ejector 361-1 is in the unlocked state, the lock unit 362-1 is positioned on the side of a handle 364-1 provided on the tip of the ejector 361-1, and a cutout portion 365-1 provided on the lock unit 362-1 is not fitted into the front plate 351 (FIG. 6A).

When the ejector 361-1 is in the unlocked state, as illustrated in FIG. 6B, the ejector 361-1 is rotatable anticlockwise, and when it is rotated by an angle that is equal to or greater than a prescribed angle, the board 301-1 is pushed out of the chassis 201 (locking release), and it becomes possible to remove the board 301-1.

When the lock unit 362-1 is moved in the direction of the root of the ejector 361-1, the cutout portion 365-1 is fitted into the front plate 351 (FIG. 6C).

Accordingly, the ejector 361-1 is fixed onto the front plate 351 and the ejector 361-1 is put into a locked state. Therefore, even when a cable or the like touches the ejector 361-1, the ejector 361-1 does not move, and the malfunction is prevented.

Next, the states of the ejector and the switches during the insertion of the board, after the insertion of the board, and while the ejector is locked are explained.

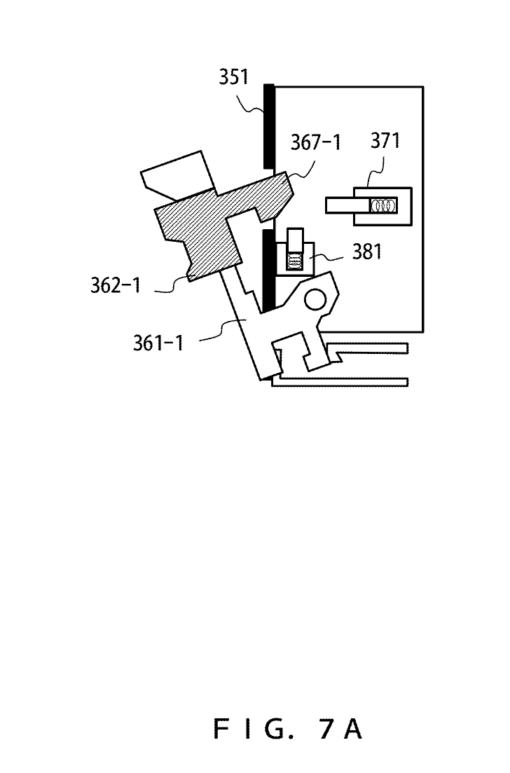

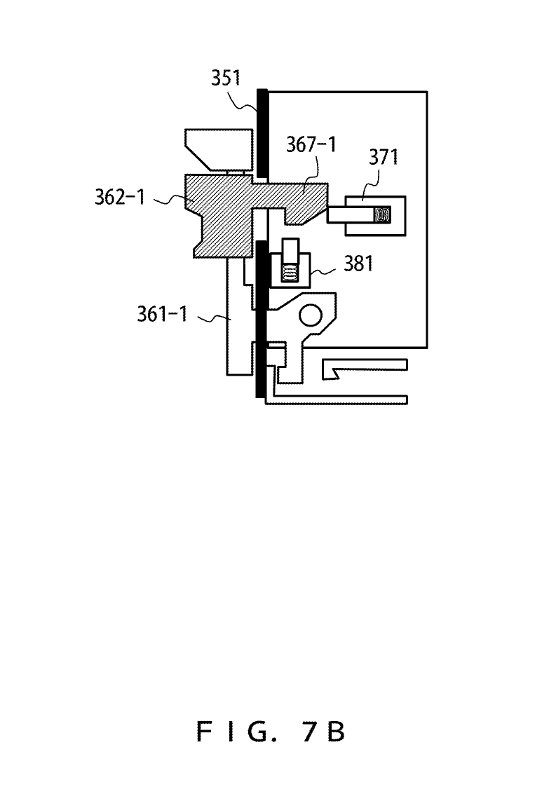

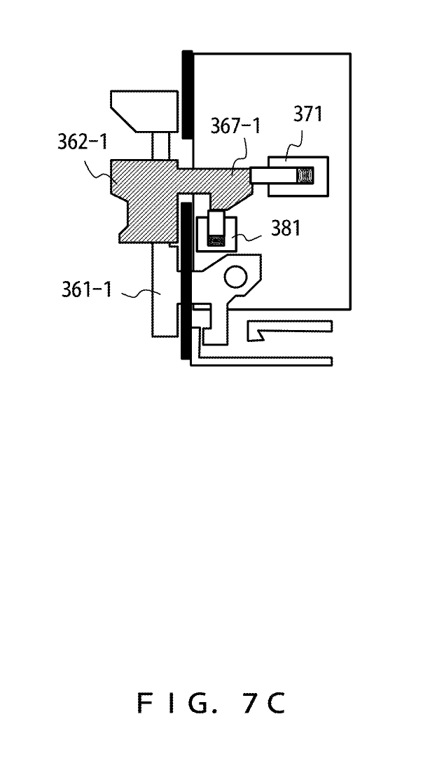

FIG. 7A is a diagram of the ejector during the insertion of the board according to the embodiment.

FIG. 7B is a diagram of the ejector after the insertion of the board according to the embodiment.

FIG. 7C is a diagram of the ejector while the ejector is locked according to the embodiment.

When inserting the board 301 into the chassis 201, the power supply switch 371 and the lock switch 381 are not pressed down and they are in the off state (FIG. 7A). Meanwhile, the tip of the ejector 361-1 is at a position away from the front plate 351 (the open state).

According to the insertion of the board 301-1, the ejector 361-1 rotates clockwise, and a protruding portion 367-1 provided in the lock unit 362-1 passes through a hole provided on the front plate 351. Meanwhile, the tip of the ejector 361-1 is at a position close to the front plate 351 (the closed state).

Meanwhile, the ejector 361-1 may be configured to rotate according to the insertion of the board 301-1, or the operator may rotate the ejector 361-1 when the insertion of the board 301-1 is completed, to lock the board 301-1 on the chassis 201.

When the insertion of the board 301-1 into the chassis 201 is completed, the power supply switch 371 is pressed by the protruding portion 367-1 of the lock unit 362-1, and the power supply switch 371 is put into the on state (FIG. 7B).

When the lock unit 362-1 is slid in the direction of the root of the ejector 361-1 and the ejector 361-1 is locked, the lock switch 381 is pressed down by the protruding portion 367-1 of the lock unit 362-1, and the lock switch 381 is put into the on state (FIG. 7C). Meanwhile, the power supply switch 371 is also in the on state.

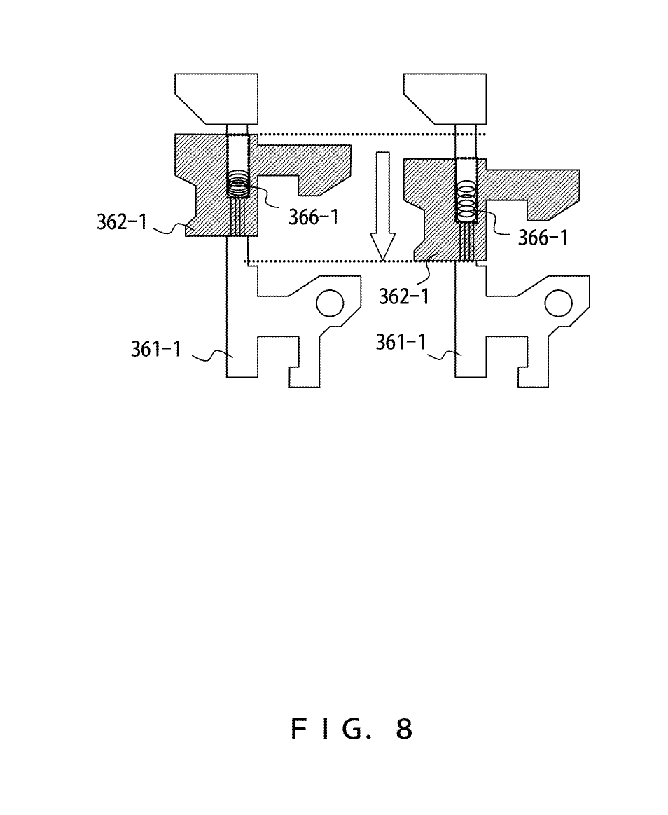

FIG. 8 is a diagram illustrating the configuration and the operations of the ejector according to the embodiment.

The left side of FIG. 8 represents the unlocked state, and the right side represents the locked state.

A spring 366-1 is provided inside the ejector 361-1, and by means of the spring 366-1, the lock unit 362-1 autonomously slides in the direction (the direction of the arrow in FIG. 8) of the root of the ejector 361-1 (the right side of FIG. 8). Accordingly, the ejector 361-1 automatically maintains the locked state when the insertion of the board 301-1 is completed.

When removing the board 301-1, the user makes the lock unit 362-1 slide in the direction of the tip of the ejector (the left side of the FIG. 8). Accordingly, the ejector 361-1 is put into the unlocked state, and it becomes possible for the user to move the ejector 361-1 to remove the board 301-1.

Meanwhile, the spring is an example of an elastic member, and for example, rubber or the like may also be used.

Meanwhile, the ejector in the FIG. 8 is an example, and in an embodiment, a spring may be provided as described above; however, the spring does not have to be provided.

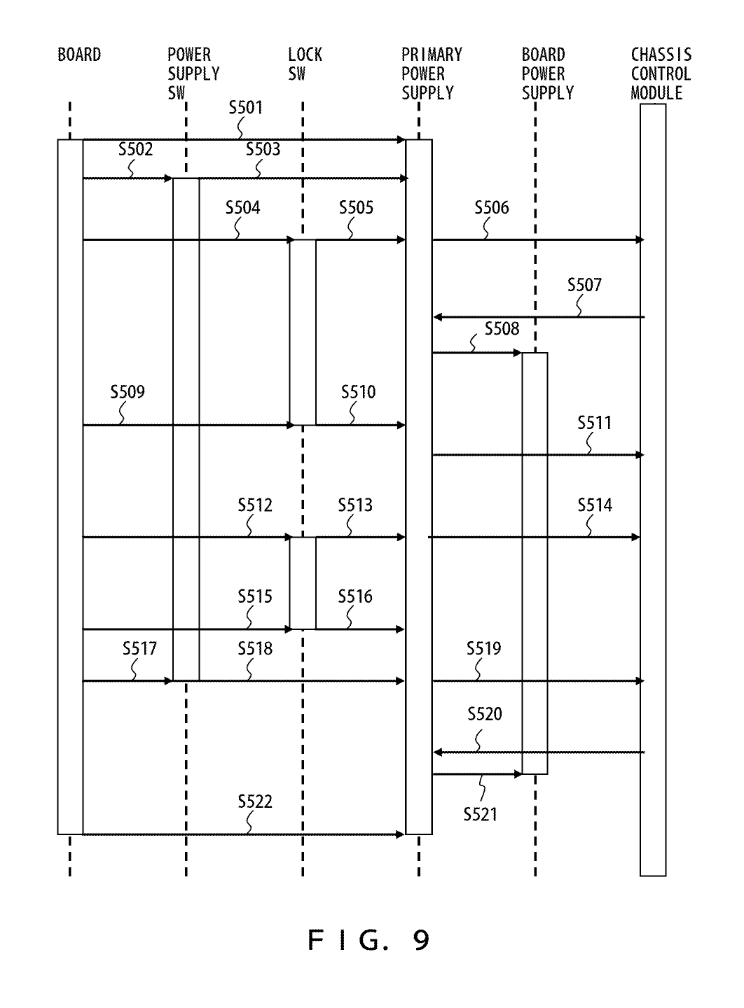

FIG. 9 is a sequence diagram of a power supply control process according to the embodiment.

Here, the process from the insertion to the removal of the board 301-1 is explained.

In step S501, the board 301-1 is inserted into the chassis 201, the connector 341 connects to the connector 206 of the backplane 205, power is supplied, and the primary power supply 312 turns on.

In step S502, the insertion of the board 301-1 is completed, the ejector 361-1 rotates clockwise, and the lock unit 362-1 is pushed into the board side (the ejector closing operation).

In step S503, the power supply switch 371 is pressed down by the lock unit 362-1, and the power supply switch 371 turns on.

In step S504, in order to lock the ejector 361-1, the lock unit 362-1 slides in the direction of the root of the ejector 361-1 (the ejector locking operation).

In step S505, the lock switch 381 is pressed down by the lock unit 362-1, and the lock switch 381 turns on.

In step S506, the power supply switch 371 and the lock switch 381 have both been turned on, and therefore, the board monitoring circuit 313 reports the closing of the ejector 361-1 to the chassis control module 202.

In step S507, the chassis control module 202 reports the permission to turn on the board power supply to the board monitoring circuit 313. The board monitoring circuit 313 that received the report reports the permission to turn on the board power supply to the power supply control circuit 314.

In step S508, the power supply control circuit 314 turns on the board power supply 318. Accordingly, power is supplied to the main circuit 321, making the main circuit 321 start its operations.

In step S509, it is assumed that the hand of the operator or a cable or the like touches the lock unit 362-1, moving the lock unit 362-1 in a direction in which the ejector 361-1 is put into the unlocked state and such that the ejector 361-1 is put into the unlocked state.

In step S510, the lock switch 381 is no longer pressed down, and the lock switch 381 turns off. The power supply control circuit 314 starts counting the time to measure the time during which the ejector 361-1 is in the unlocked state.

It is assumed that ejector 361-1 stays in the unlocked state.

In step S511, after a prescribed period of time (for example, after five minutes) since the ejector 361-1 was put into the unlocked state, the power supply control circuit 314 reports “unlocked” to the board monitoring circuit 313 (for example, the power supply control circuit 314 turns on a unlock detection signal). The board monitoring circuit 313 that received the report reports “unlocked” to the chassis control module 202. The chassis control module 202 that received the report reports “unlocked” to the administrator. For example, the chassis control module 202 executes a process such as a process to display a warning (for example, a message that indicates that the ejector is unlocked) on a display apparatus attached to the server 101, or a process to transmit a warning message to a management apparatus connected through a network.

In step S512, the ejector 361-1 is put into the locked state again. That is, the lock unit 362-1 slides in the direction of the root of the ejector 361-1.

In step S513, the lock switch 381 is pressed down by the lock unit 362-1, and the lock switch 381 turns on.

In step S514, the power supply control circuit 314 reports “locked” to the board monitoring circuit 313 (for example, the power supply control circuit 314 turns off the unlock detection signal). The board monitoring circuit 313 that received the report reports “locked” to the chassis control module 202.

In step S515, the ejector 361-1 moves in the direction for putting the ejector 361-1 into the unlocked state, and the ejector 361-1 is put into the unlocked state.

In step S516, the lock switch 381 is no longer pressed down, and the lock switch 381 turns off.

In step S517, the ejector 361-1 is rotated, and the locking of the board 301-1 is released.

In step S518, according to the rotation of the ejector 361-1, the lock unit 362-1 moves away from the power supply switch 371, the power supply switch 371 is no longer pressed down, and the power supply switch 371 turns off.

In step S519, the power supply switch 371 and the lock switch 381 have both been turned off, and therefore, the board monitoring circuit 313 reports the opening of the ejector 361-1 to the chassis control module 202.

In step S520, the chassis control module 202 reports the permission to turn off the board power supply to the board monitoring circuit 313. The board monitoring circuit 313 that received the report reports the permission to turn off the board power supply to the power supply control circuit 314.

In step S521, the power supply control circuit 314 turns off the board power supply 318. Accordingly, the power supply to the main circuit 321 stops, and the main circuit 321 stops its operations.

In step S522, the user removes the board 301-1.

Accordingly, the primary power supply 312 turns off, the power supply to the control circuit stops, and the control circuit stops its operations.

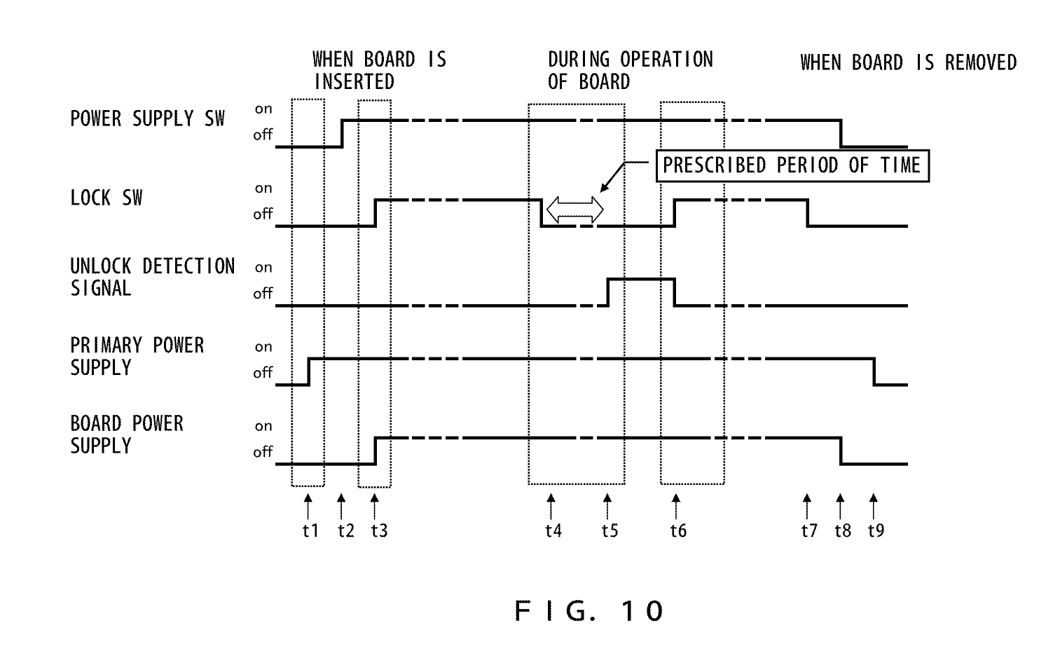

FIG. 10 is a timing that illustrates the state of the board according to the embodiment.

Here, the process from the insertion to the removal of the board 301-1 is explained.

FIG. 10 presents the state of each of the power supply switch 371, the lock switch 381, the unlock detection signal, the primary power supply 312, and the board power supply 318, in this order from the top.

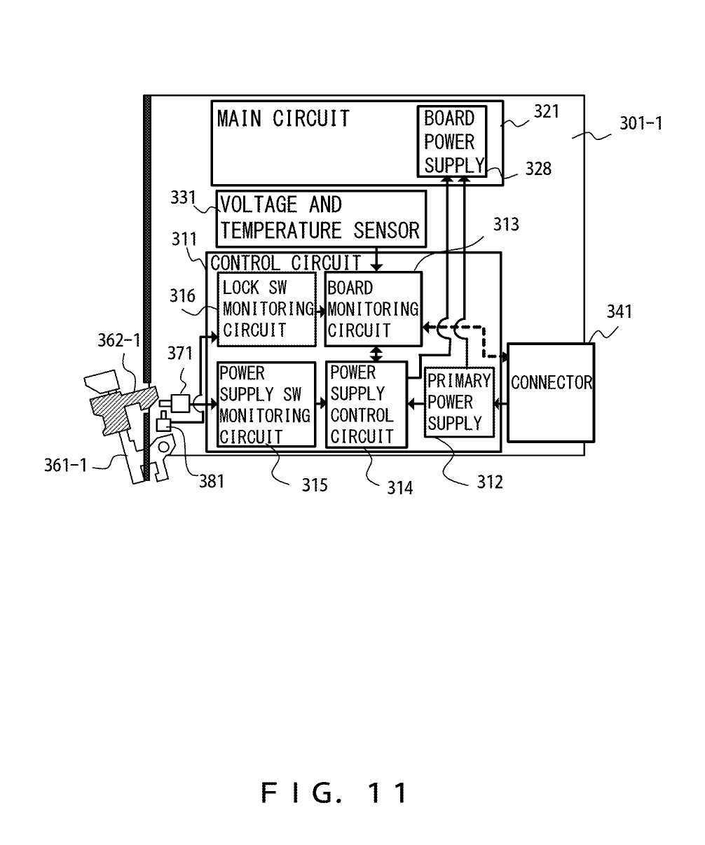

FIG. 11 is a diagram illustrating the state of the board before the insertion of the board.

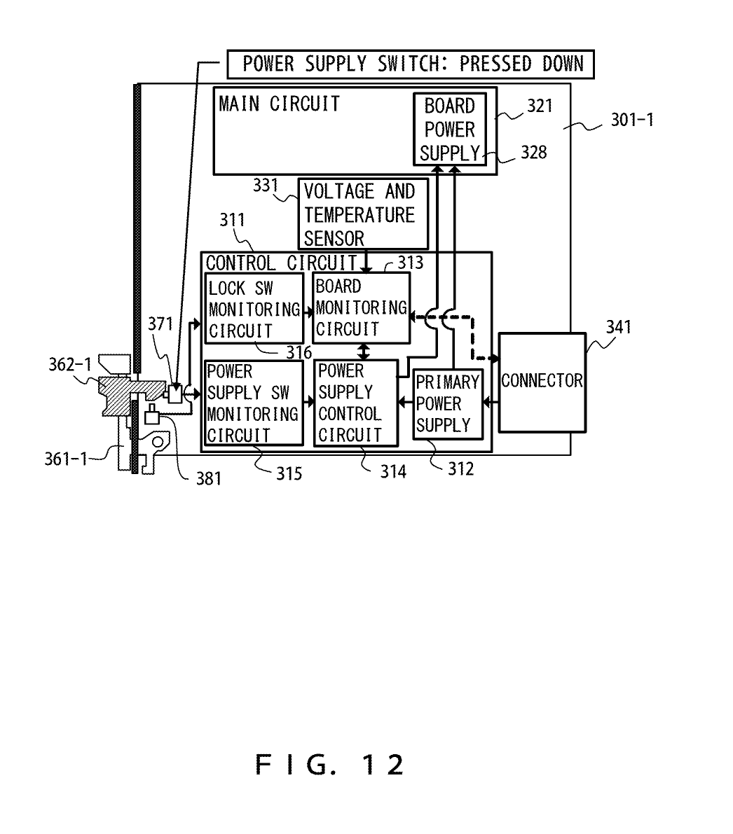

FIG. 12 is a diagram illustrating the state of the board at the time of the completion of the insertion of the board.

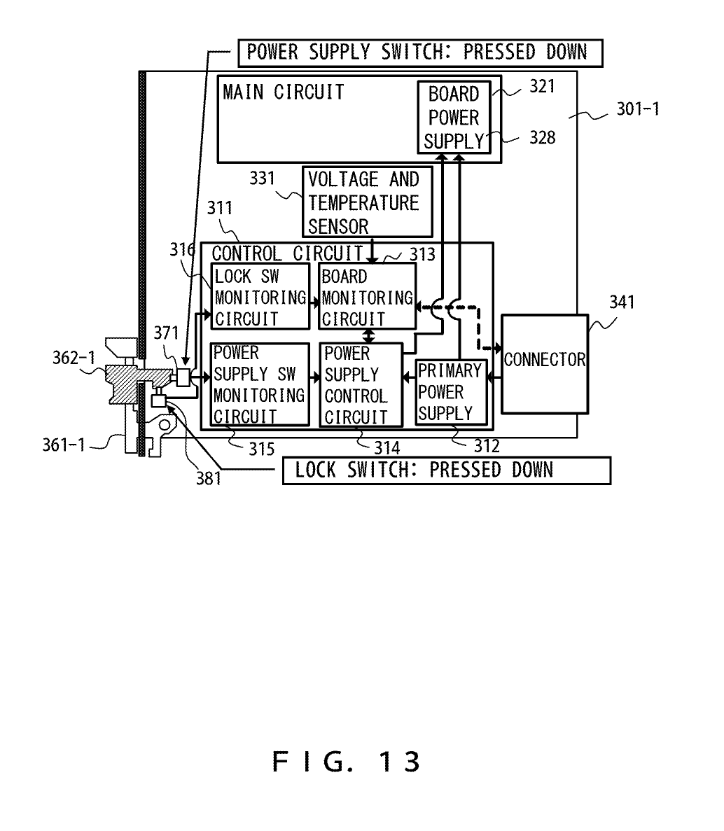

FIG. 13 is a diagram illustrating the board while the ejector is in the locked state.

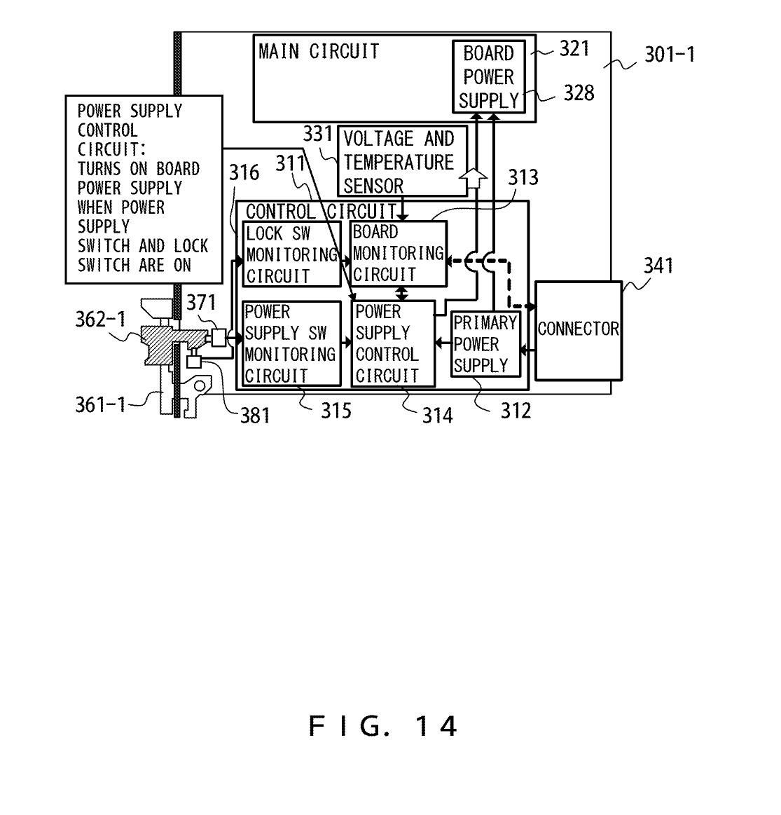

FIG. 14 is a diagram illustrating the state of the board while the board power supply is on.

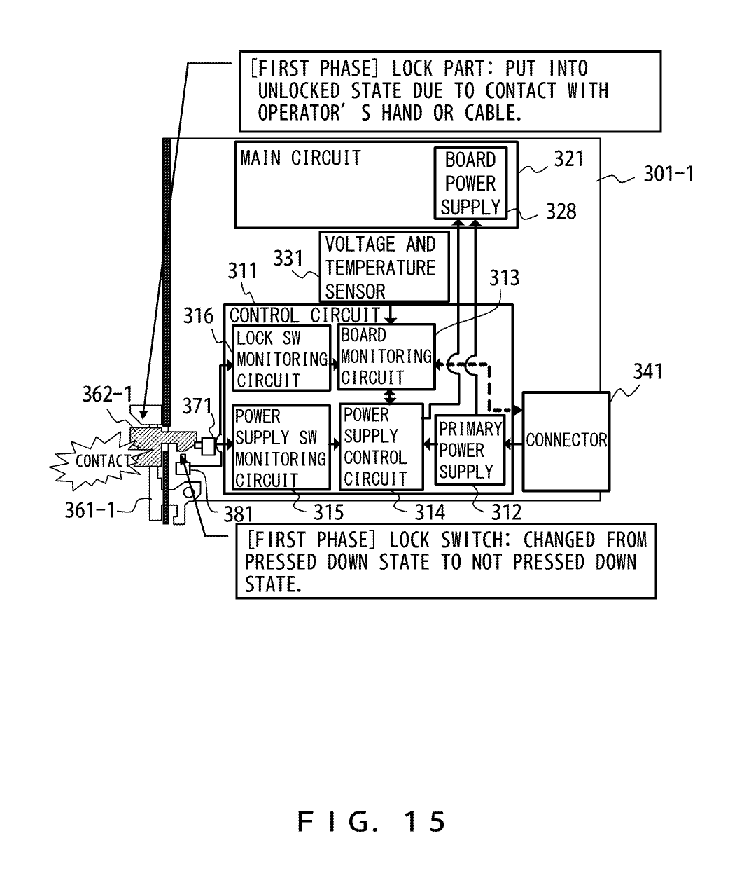

FIG. 15 is a diagram illustrating the state of the board while the ejector is in the unlocked state.

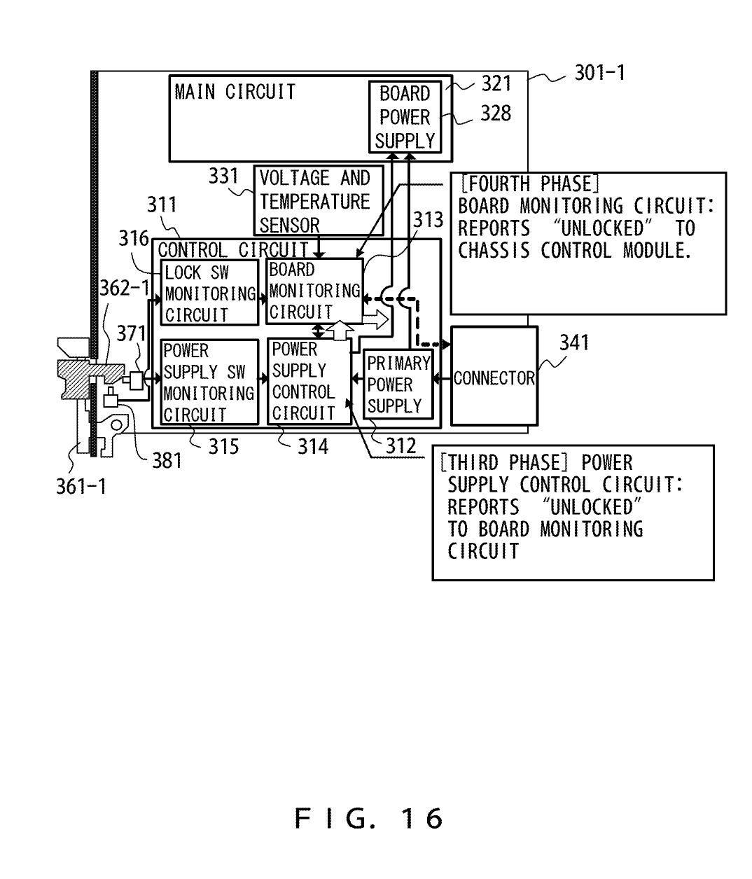

FIG. 16 is a diagram illustrating the state of the board after a prescribed period of time since the ejector was put into the unlocked state.

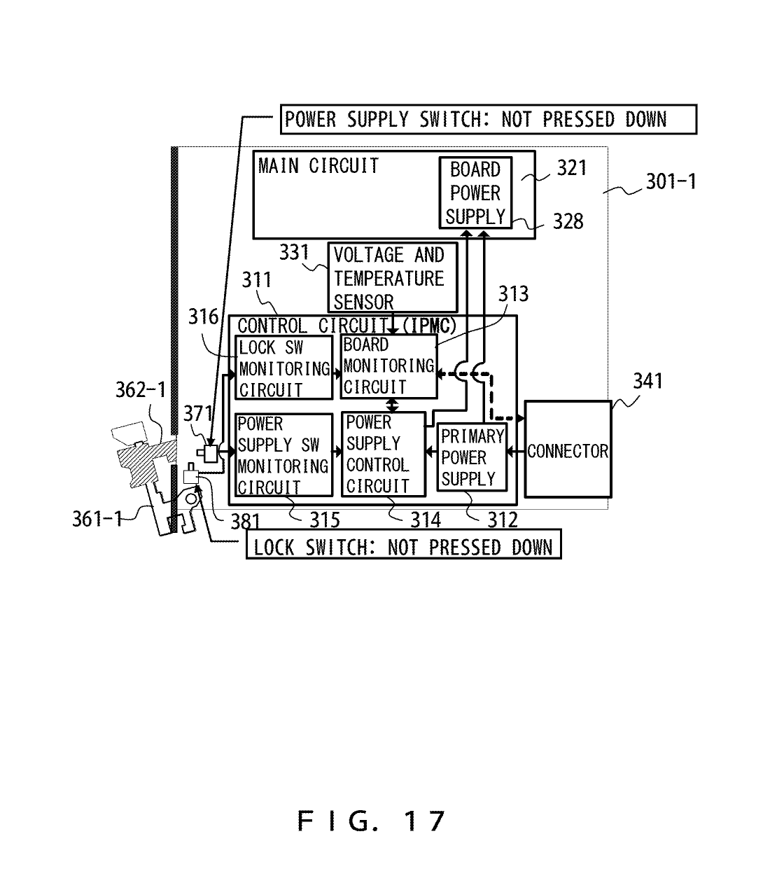

FIG. 17 is a diagram illustrating the state of the board while the ejector is open.

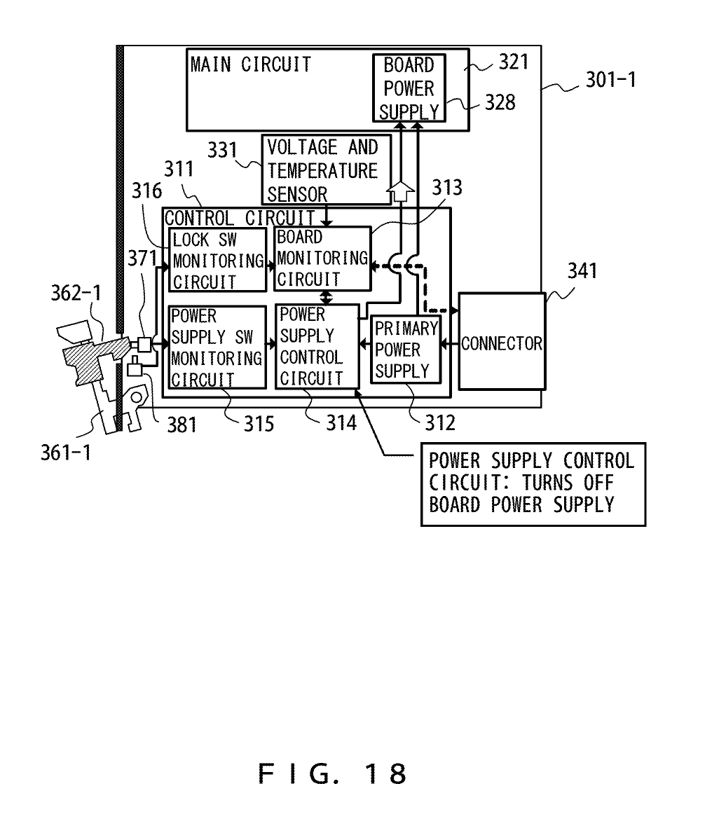

FIG. 18 is a diagram illustrating the state of the board while the board power supply is off.

First, before the insertion of the board 301-1 into the chassis 201, the tip of the ejector 361-1 is at a position away from the front plate 351 (the open state), the power supply switch 371 and the lock switch 381 are not pressed down, and they are in the off state (FIG. 11).

When the board 301-1 is inserted into the chassis 201, the connector 341 connects to the connector 206 of the backplane 205, power is supplied, and the primary power supply 312 turns on (time t1).

When the insertion of the board 301-1 is completed, the ejector 361-1 rotates clockwise and the lock unit 362-1 is pushed into the board side, the power supply switch 371 is pressed down by the lock unit 362-1, and the power supply switch 371 turns on (FIG. 12, time t2).

Then, in order to lock the ejector 361-1, the lock unit 362-1 slides, the lock switch 381 is pressed down by the lock unit 362-1, and the lock switch 381 turns on (FIG. 13). At this point, the power supply switch 371 and the lock switch 381 have both been turned on, and therefore, the power supply control circuit 314 turns on the board power supply 318 (FIG. 14, time t3).

After that, it is assumed that the hand of the operator or a cable or the like touches the lock unit 362-1, moving the lock unit 362-1 in a direction for putting the ejector 361-1 into the unlocked state and such that the ejector 361-1 is put into the unlocked state. At this time, the lock switch 381 is no longer pressed down, and the lock switch 381 turns off (FIG. 15, time t4). The power supply control circuit 314 starts counting the time to measure the time during which the ejector 361-1 is in the unlocked state.

It is assumed that the ejector 361-1 stays in the unlocked state after time t4. At time t5 after a prescribed period of time from time t4, the power supply control circuit 314 reports “unlocked” to the board monitoring circuit 313 (the power supply control circuit 314 turns on the unlock detection signal).

Upon receiving the report of “unlocked”, the board monitoring circuit 313 reports “unlocked” to the chassis control module 202 (FIG. 16).

At time t6, when the ejector 361-1 is put into the locked state again, the lock switch 381 turns on, and also the unlock detection signal is turned off.

When removing the board 301-1, first, the ejector 361-1 is put into the unlocked state by making the lock unit 362-1 slide. Accordingly, the lock switch 381 turns off (time t7).

Then, the ejector 361-1 is rotated in the direction (anticlockwise in FIG. 17) for moving the tip of the ejector 361-1 away from the board 301-1, to release the locking of the board 301-1. According to the rotation of the ejector 361-1, the lock unit 362-1 moves away from the power supply switch 371, the power supply switch 371 is no longer pressed down, and the power supply switch 371 turns off (FIG. 17).

The power supply switch 371 and the lock switch 381 have been turned off, and therefore, the power supply control circuit 314 turns off the board power supply 328 (FIG. 18, time t8).

The board 301-1 is removed from the chassis 201, the connector 341 is disconnected from the connector 206, the power supply to the board 301-1 stops, and the primary power supply 312 turns off (time t9).

According to the information processing apparatus according to the embodiment, the power supply of the main circuit is turned on when the lock switch is on. Therefore, it is possible to prevent the power supply from being turned on in the unlocked state. Accordingly, it is possible to prevent a malfunction such as the turning off of the power supply switch caused when the operator terminates a task without locking the ejector and the ejector is moved due to an accident such as contact with the ejector.

According to the information processing apparatus according to the embodiment, the unlocked state is reported when the state in which the lock switch is off while the power supply of the main circuit is on continues for a prescribed period of time. Accordingly, the administrator is able to know that the ejector is in the unlocked state. The administrator puts the ejector into the locked state when it is reported that the ejector is in the unlocked state. Therefore, it is possible to prevent a malfunction such as the turning off of the power supply switch caused when the ejector is left in the unlocked state and the ejector is moved due to an accident such as contact with the ejector.

All examples and conditional language provided herein are intended for pedagogical purposes to aiding the reader in understanding the invention and the concepts contributed by the inventor to further the art, and are not to be construed as being limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An information processing apparatus comprising a removable board, wherein
the board includes
a first control circuit which controls the board,
a second control circuit which controls a power supply of the first control circuit,
a first locking unit which is capable of locking the board and releasing a locking of the board,
a second locking unit which locks the first locking unit, and
a lock switch which turns on when the first locking unit is locked by the second locking unit,
the second control circuit turns on the power supply of the first control circuit when the lock switch is on.

2. The information processing apparatus according to claim 1, wherein
the board further comprises a power supply switch which turns on when the board is locked in the information processing apparatus by the first locking unit,
the second control circuit turns on the power supply of the first control circuit when the power supply switch and the lock switch are on.

3. The information processing apparatus according to claim 1, wherein the second control circuit reports that the first locking unit is unlocked when the lock switch turns off after the power supply of the first control circuit turns on and a state in which the lock switch is off continues for a period of time that is equal to or greater than a prescribed period of time.

4. A power supply control method executed by a computer comprising a removable board that includes a first control circuit which controls the board, a second control circuit which controls a power supply of the first control circuit, a first locking unit which is capable of locking the board and releasing a locking of the board, a second locking unit which locks the first locking unit, and a lock switch which turns on when the first locking unit is locked by the second locking unit, the power supply control method comprising:
monitoring, by the computer, the lock switch, and
turning on, by the computer, the power supply of the first control circuit when the lock switch is on.

5. The power supply control method according to claim 4, wherein
the board further comprises a power supply switch which turns on when the board is locked in the computer by the first locking unit, and
in the turning on of the power supply of the first control circuit, the power supply of the first control circuit is turned on when the power supply switch and the lock switch are on.

6. The power supply control method according to claim 4, further comprising reporting that the first locking unit is unlocked, when the lock switch turns off after the power supply of the first control circuit turns on and a state in which the lock switch is off continues for a period of time that is equal to or greater than a prescribed period of time.
